(19) United States
(12) Patent Application Publication
(10) Pub. No.: US 2012/0021549 A1
(43) Pub. Date: Jan. 26, 2012

(54) METHOD FOR GROWING CRYSTALS OF NITRIDE SEMICONDUCTOR, AND PROCESS FOR MANUFACTURE OF SEMICONDUCTOR DEVICE

(75) Inventors: Masaki Fujikane, Osaka (JP); Akira Inoue, Osaka (JP); Ryou Kato, Osaka (JP); Toshiya Yokogawa, Nara (JP)

(73) Assignee: PANASONIC CORPORATION, Osaka (JP)

(21) Appl. No.: 13/260,434

(22) PCT Filed: Mar. 24, 2010
(86) PCT No.: PCT/JP2010/002058

§ 371 Date: Sep. 26, 2011

(30) Foreign Application Priority Data
Apr. 3, 2009 (JP) 2009-091018

(51) Int. Cl. H01L 33/32; H01L 21/20

(52) U.S. Cl. 438/46; 438/478; 257/E21.09; 257/E33.023

(57) ABSTRACT

A nitride semiconductor layer formation method includes the steps of: (S1) placing a substrate in a reaction chamber, the substrate including a −r-plane nitride semiconductor crystal at least in an upper surface; (S2) increasing a temperature of the substrate by heating the substrate placed in the reaction chamber; and (S3) growing a nitride semiconductor layer on the substrate. In the temperature increasing step (S2), a nitrogen source gas and a Group III element source gas are supplied into the reaction chamber.

### TECHNICAL FIELD

The present invention relates to a crystal growth method of a nitride semiconductor with the use of metallorganic chemical vapor deposition. The present invention also relates to a fabrication method of a nitride-based semiconductor device. More particularly, the present invention relates to a GaN-based semiconductor light-emitting device such as a light-emitting diode or a laser diode that operates at wavelengths over the ultraviolet range and the entire visible radiation range, which covers blue, green, orange and white parts of the spectrum. Such a light-emitting device is expected to be applied to various fields of technologies including display, illumination and optical information processing in the near future.

### BACKGROUND ART

A nitride semiconductor including nitrogen (N) as a Group V element is a prime candidate for a material to make a short-wave light-emitting device because its bandgap is sufficiently wide. Among other things, gallium nitride-based compound semiconductors (which will be referred to herein as “GaN-based semiconductors”) have been researched and developed particularly extensively. As a result, blue light-emitting diodes (LEDs), green LEDs, and semiconductor laser diodes made of GaN-based semiconductors have already been used in actual products.

A gallium nitride-based semiconductor has a wurtzite crystal structure. FIG. 1 schematically illustrates a unit cell of GaN. In an AlₐGa_{b}In_{c}N (where 0≦a, b, c≦1 and a+b+c=1) semiconductor crystal, some of the Ga atoms shown in FIG. 1 may be replaced with Al and/or In atoms.

FIG. 2 shows four primitive translation vectors a₁, a₂, a₃ and c, which are generally used to represent planes of a wurtzite crystal structure with four indices (i.e., hexagonal indices). The primitive translation vector c runs in the [0001] direction, which is called a “c-axis”. A plane that intersects with the c-axis at right angles is called either a “c-plane” or a “(0001) plane”. It should be noted that the “c-axis” and the “c-plane” are sometimes referred to as “C-axis” and “C-plane”, respectively.

The wurtzite crystal structure has other typical crystallographic plane orientations than the c-plane, as shown in FIG. 3. FIG. 3(a) shows a (0001) plane. FIG. 3(b) shows a (10-10) plane. FIG. 3(c) shows a (11-20) plane. FIG. 3(d) shows a (10-12) plane. As used herein, attached on the left-hand side of a Miller-Bravais index in the parentheses means a “bar” (a negative direction index). The (0001) plane, the (10-10) plane, the (11-20) plane, and the (10-12) plane are the c-plane, the m-plane, the a-plane, and the r-plane, respectively. The m-plane and the a-plane are “non-polar planes” that are parallel to the c-axis (primitive translation vector c), and the r-plane is a “semi-polar plane”.

For years, a light-emitting device in which a gallium nitride-based compound semiconductor is used is fabricated by means of “c-plane growth”. As used herein, the “X-plane growth” means epitaxial growth that is produced perpendicularly to the X plane (where X-c, m, a, or r) of a hexagonal wurtzite structure. As for the X-plane growth, the X plane will be sometimes referred to herein as a “growing plane”. Furthermore, a layer of semiconductor crystals that have been formed as a result of the X-plane growth will be sometimes referred to herein as an “X-plane semiconductor layer”.

When a light-emitting device is fabricated using a semiconductor multilayer structure formed by means of the c-plane growth, strong internal polarization occurs in a direction perpendicular to the c-plane (c-axis direction) because the c-plane is a polar plane. The reason for occurrence of the polarization is that, on the c-plane, there is a shift in the c-axis direction between the positions of a Ga atom and a N atom. If such polarization occurs in an emission section, a quantum confinement Stark effect of carriers occurs. This effect reduces the probability of radiative recombination of carriers in the emission section and accordingly reduces the emission efficiency.

In view of such circumstances, in recent years, intensive research has been carried out on growth of a gallium nitride-based compound semiconductor on a non-polar plane, such as m-plane and a-plane, and a semi-polar plane, such as r-plane. If a non-polar plane is available as the growing plane, no polarization occurs in the layer thickness direction (crystal growth direction) of the emission section. Therefore, the quantum confinement Stark effect does not occur. Thus, a light-emitting device which potentially has high efficiency can be fabricated. Even when the growing plane is a semi-polar plane, the influence of the quantum confinement Stark effect can be greatly reduced.

Patent Document 1 discloses a method of forming a nitride compound semiconductor layer by means of m-plane growth.

### CITATION LIST

### Patent Literature

Patent Document 1: Japanese Laid-Open Patent Publication No. 2008-91488

### SUMMARY OF INVENTION

### Technical Problem

It was found that, when a GaN crystal layer is grown on a −r-plane GaN substrate using the same growth method as the conventional c-plane growth, the surface morphology greatly varies depending on the thickness of the grown GaN layer. As will be described later in detail, when the thickness of the GaN layer is 5 μm or less, a stripe-pattern morphology or pits are formed in the surface of the GaN layer, so that the surface has large roughness on the order of several micrometers. When there is such roughness in the surface of GaN layer, it is difficult to uniformly form a thin light-emitting layer (typical thickness: about 3 nm) over the GaN layer. When an electrode is formed on such an irregular surface to fabricate a light-emitting device, there is a probability that the pn junction may be shortcircuited because formation of semiconductor layers is insufficient.

From the above reasons, a light-emitting device cannot be realized by means of −r-plane growth without forming a thick GaN layer such that no roughness is formed in the surface. Specifically, the thickness of the GaN layer needs to be 5.0 μm or more, more preferably 7.5 μm or more. With such a thick grown GaN layer, the flatness of the surface can be secured, while the throughput of fabrication however decreases. Thus, it greatly impedes mass production.

The present invention was conceived with the view of solving the above problems. One of the objects of the present invention is to provide a novel nitride semiconductor layer formation method which is capable of securing the surface flatness of a GaN layer even when the grown GaN layer is not thick.

Another one of the objects of the present invention is to provide a semiconductor device fabrication method which includes the step of forming a nitride semiconductor layer in accordance with the above nitride semiconductor layer formation method.

### Solution to Problem

The first nitride semiconductor layer formation method of the present invention, in which a nitride semiconductor layer is grown by means of metallorganic chemical vapor deposition, includes the steps of: (S1) placing a substrate in a reaction chamber, the substrate including a nitride semiconductor crystal whose surface is a −r-plane at least in an upper surface; (S2) increasing a temperature of the substrate by heating the substrate placed in the reaction chamber; and (S3) growing a nitride semiconductor layer on the substrate after the temperature increasing step (S2), wherein the temperature increasing step (S2) includes supplying a nitrogen source gas and a Group III element source gas into the reaction chamber.

In one embodiment, the temperature increasing step (S2) includes forming a continuous early-stage grown layer of a nitride semiconductor on the substrate during the increase of the temperature.

In one embodiment, throughout the temperature increasing step (S2) and the growth step (S3), the surface of the nitride semiconductor crystal is maintained smooth.

In one embodiment, where a ratio of a supply rate of the nitrogen source gas to a supply rate of the Group III element source gas is referred to as a V/III ratio, a V/III ratio in the temperature increasing step (S2) is greater than a V/III ratio in the growth step (S3).

In one embodiment, a V/III ratio in the temperature increasing step (S2) is set to 4000 or higher.

In one embodiment, a supply rate of the Group III element source gas supplied into the reaction chamber in the temperature increasing step (S2) is smaller than a supply rate of the Group III element source gas supplied into the reaction chamber in the growth step (S3).

In one embodiment, the nitrogen source gas is an ammonium gas.

In one embodiment, the Group III element source gas is a Ga source gas.

In one embodiment, the temperature increasing step (S2) includes increasing the temperature of the substrate from a temperature lower than 850° C. to a temperature equal to or higher than 850° C.

In one embodiment, the supply of the Group III element source gas into the reaction chamber is started before the temperature of the substrate reaches 850° C.

In one embodiment, the supply of the nitrogen source gas and the Group III element source gas into the reaction chamber is started in the middle of the increase of the temperature in the temperature increasing step (S2).

In one embodiment, the temperature increasing step (S2) includes increasing the temperature from a thermal cleaning temperature to a growth temperature for an n-type nitride semiconductor layer.

In one embodiment, the temperature increasing step (S2) includes increasing the temperature from a growth temperature for an InGaN active layer to a growth temperature for a p-GaN layer.

In one embodiment, the temperature increasing step (S2) includes increasing the temperature from a thermal cleaning temperature to a growth temperature for an n-type nitride semiconductor layer and increasing the temperature from a growth temperature for an InGaN active layer to a growth temperature for a p-GaN layer.

In one embodiment, the growth step (S3) includes growing the nitride semiconductor layer while the temperature of the substrate is maintained at 990° C. or higher.

In one embodiment, the growth step (S3) includes growing the nitride semiconductor layer to a thickness equal to or smaller than 5 μm.

In one embodiment, a semiconductor device fabrication method of the present invention includes the steps of: preparing a substrate including a nitride semiconductor crystal whose surface is a −r-plane at least in an upper surface; and forming a semiconductor multilayer structure on the substrate, wherein the step of forming the semiconductor multilayer structure includes forming a nitride semiconductor layer in accordance with the first nitride semiconductor layer formation method of the present invention.

In one embodiment, the method further includes the step of removing at least part of the substrate.

An epi wafer fabrication method of the present invention includes the steps of: preparing a substrate including a nitride semiconductor crystal whose surface is a −r-plane at least in an upper surface; and forming a nitride semiconductor layer on the substrate in accordance with the first nitride semiconductor layer formation method of the present invention.

The second nitride semiconductor layer formation method of the present invention, in which a nitride semiconductor layer is grown by means of metallorganic chemical vapor deposition, includes the steps of: (S1) placing a substrate in a reaction chamber, the substrate including a nitride semiconductor crystal at least in an upper surface, and an angle formed by a normal to the upper surface and a normal to a −r-plane being from 1° to 5°; (S2) increasing a temperature of the substrate by heating the substrate placed in the reaction chamber; and (S3) growing a nitride semiconductor layer on the substrate after the temperature increasing step (S2), wherein the temperature increasing step (S2) includes supplying a nitrogen source gas and a Group III element source gas into the reaction chamber.

In one embodiment, the substrate has an inclination in a [10-12] direction or a-axis direction.

### Advantageous Effects of Invention

According to the present invention, a −r-plane nitride semiconductor layer which has a smooth surface can be formed even when the thickness of the grown nitride semiconductor layer is 400 nm or less. Accordingly, the growth time of that layer can be greatly reduced, and the throughput of the crystal growth step can be increased. The same effect can be achieved even when using a GaN substrate whose principal surface is inclined from the −r-plane by an angle of 1° or greater.

### BRIEF DESCRIPTION OF DRAWINGS

FIG. 1 is a perspective view schematically showing a unit lattice of GaN.

FIG. 2 is a perspective view showing primitive translation vectors a₁, a₂, a₃, c of a wurtzite crystal structure.

FIGS. 3(a) to 3(d) are schematic diagrams showing representative crystallographic plane orientations of a hexagonal wurtzite structure.

FIG. 4 is a diagram showing an example of the configuration of a reaction chamber of a MOCVD apparatus.

FIG. 5 is a chart which illustrates a conventional process.

FIGS. 6(a) and 6(b) are optical-microscopic images of the surface of a +r-plane GaN layer and a −r-plane GaN layer formed by a conventional method so as to have a thickness of 400 nm (growth temperature: 1090° C.)

FIG. 7 is another optical-microscopic image of the surface of a 400 nm thick −r-plane GaN layer formed by a conventional method (growth temperature: 990° C.)

FIG. 8 is an optical-microscopic image of the surface of a 400 nm thick +c-plane GaN layer formed by a conventional method.

FIG. 9 is a diagram schematically showing an atomic arrangement in the surface of a +c-plane GaN layer.

FIG. 10A is a diagram schematically showing an atomic arrangement in the surface of a +r-plane GaN layer.

FIG. 10B is a diagram schematically showing an atomic arrangement in the surface of a −r-plane GaN layer.

FIG. 11 is a flowchart which illustrates a formation method of a nitride semiconductor layer according to the present invention.

FIG. 12 is a chart which illustrates a process of the present invention.

FIG. 13 is a chart which illustrates another process of the present invention.

FIG. 14 is a cross-sectional view showing nitride semiconductor layers formed by a nitride semiconductor layer formation method of the present invention.

FIG. 15 is a cross-sectional view showing another nitride semiconductor layer formed by a nitride semiconductor layer formation method of the present invention.

FIG. 16 is an optical-microscopic image of a surface of a GaN layer of Example 1.

FIG. 17 is an optical-microscopic image of a surface of a GaN layer of Example 2.

FIG. 18 is a cross-sectional view showing a structure of a light-emitting device fabricated on a −r-plane GaN substrate of Example 3.

FIG. 19 is an optical-microscopic image of a surface of the light-emitting device fabricated on the −r-plane GaN substrate of Example 3.

FIG. 20 is a cross-sectional view showing a structure of a light-emitting device of Example 5.

FIG. 21 is a cross-sectional view showing a GaN substrate 110 that is an off-cut substrate and nitride semiconductor layers 120 and 130 formed on the GaN substrate 110.

FIG. 22 is a cross-sectional view showing a GaN substrate 110 that is an off-cut substrate and a nitride semiconductor layer 130 formed on the GaN substrate 110.

FIG. 23(a) is a diagram schematically showing a crystal structure of a GaN substrate (wurtzite crystal structure).

FIG. 23(b) is a perspective view which illustrates the mutual relationship among the normal to the −r-plane, the [10-12] direction, and the a-axis direction.

FIGS. 24(a) and 24(b) are cross-sectional views which illustrate the relationship between the principal surface of a GaN substrate and the −r-plane.

FIGS. 25(a) and 25(b) are cross-sectional views schematically showing the principal surface of a GaN substrate 8 and its neighboring region.

### DESCRIPTION OF EMBODIMENTS

Prior to the description of the present invention, the problems which would occur when a GaN layer is grown on a −r-plane GaN substrate in accordance with conventional metallorganic chemical vapor deposition (MOCVD) are described.

First, +c-plane, +r-plane, and −r-plane GaN substrates were prepared and washed in a mixture solution of sulfuric acid and hydrogen peroxide for 10 minutes. Thereafter, the substrates were subjected to a surface treatment with buffered sulfuric acid for 10 minutes and washed with water for 10 minutes.

Here, the +r-plane means the (−1012) plane, the (0-112) plane, the (1-102) plane, the (10-12) plane, the (01-12) plane, or the (−1102). The −r-plane means the (−101-2) plane, the (0-11-2) plane, the (1-10-2) plane, the (10-1-2) plane, the (01-1-2) plane, or the (−110-2) plane.

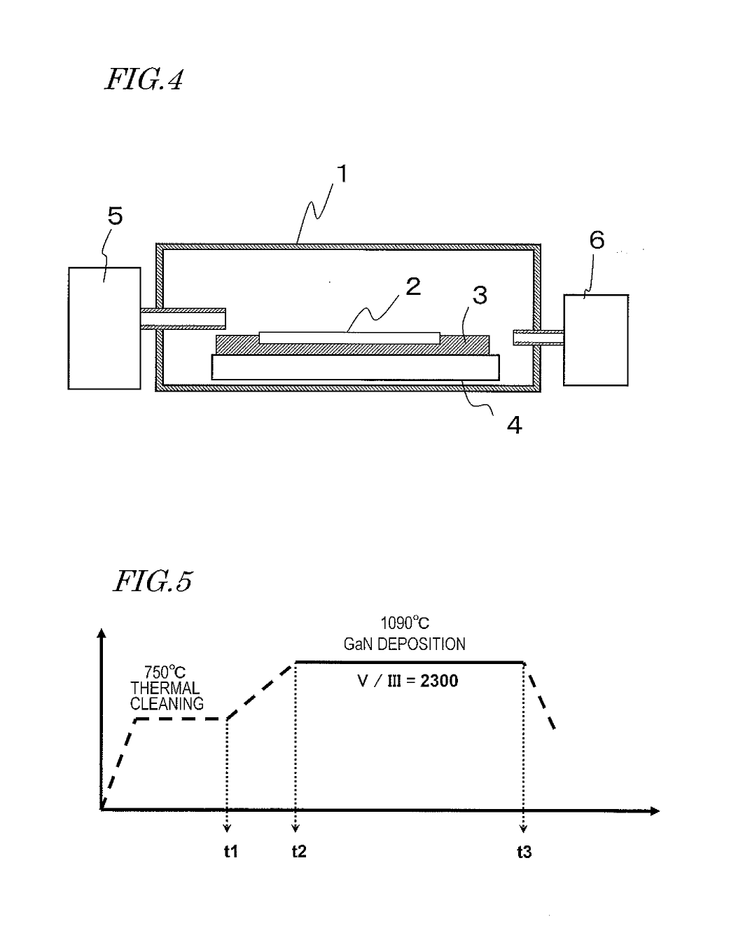

Then, growth of a GaN layer was performed in a reaction chamber 1 of a MOCVD apparatus shown in FIG. 4. Inside the reaction chamber 1 of FIG. 4, there are a quartz tray 3 for supporting a GaN substrate 2, and a carbon susceptor 4 on which the quartz tray 3 is placed. Inside the carbon susceptor 4, there is an unshown thermocouple for actually measuring the temperature of the carbon susceptor 4. The carbon susceptor 4 is heated by an unshown coil in accordance with a RF induction heating method. The substrate 2 is heated by means of conduction of heat from the carbon susceptor 4. Note that, in this specification, “substrate temperature” refers to a temperature measured by the thermocouple. This temperature is the temperature of the carbon susceptor 4 that is a direct heat source to the substrate 2. The temperature measured by the thermocouple is considered to be substantially equal to the temperature of the substrate 2.

The reaction chamber 1 shown in FIG. 4 is in communication with a gas supply device 5 such that various types of gas (source gas, carrier gas, dopant gas) are supplied from the gas supply device 5 to the inside of the reaction chamber 1. The reaction chamber 1 is also in communication with a gas exhaust device 6 such that the reaction chamber 1 can be evacuated by the gas exhaust device 6.

The GaN substrate 2, which was washed as described above, was carried into the reaction chamber 1 and placed on the quartz tray 3. Then, ammonium, hydrogen, and nitrogen were supplied into the reaction chamber 1, and in a mixture gas atmosphere of these contents, a thermal cleaning was performed on the GaN substrate 2 for 10 minutes. The thermal cleaning was performed while the substrate temperature was 750° C. After the thermal cleaning, the substrate temperature was increased to 1090° C. in the mixture gas atmosphere of ammonium, hydrogen, and nitrogen. After the substrate temperature reached 1090° C., a GaN layer was grown in a growth atmosphere of ammonium, hydrogen, nitrogen, and trimethylgallium. The V/III ratio is defined by the ratio of the supply rate of a nitrogen source gas to the supply rate of a Group III element source gas. The V/III ratio during the growth of the GaN layer was set to about 2300.

FIG. 5 is a chart which illustrates the above-described process. In the chart, the abscissa axis represents the time, and the ordinate axis represents the substrate temperature. The interval from time t1 to time t2 is a temperature increasing step. The interval from time t2 to time t3 is a growth step.

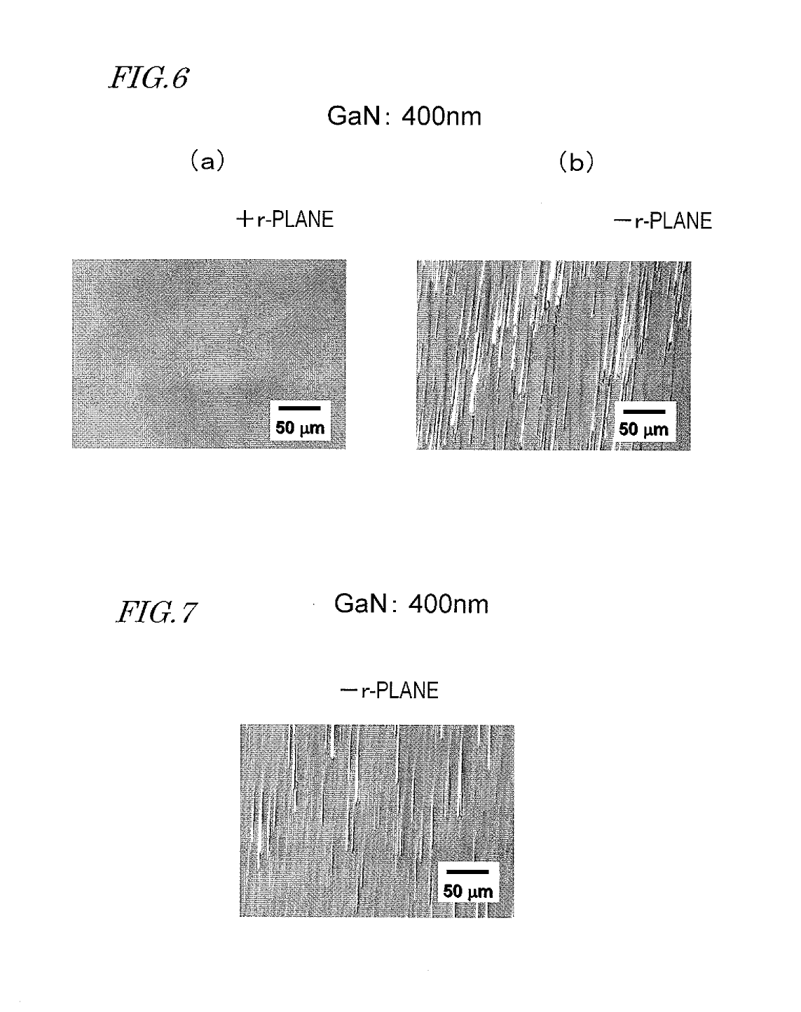

FIGS. 6(a) and 6(b) are optical-microscopic images of the surfaces of GaN layers (thickness: 400 nm) which were grown on a +r-plane GaN substrate and a −r-plane GaN substrate formed at 1090° C. FIG. 7 is another optical-microscopic image of the surface of a GaN layer (thickness: 400 nm) which was grown on a −r-plane GaN substrate at 990° C.

In the surface of the +r-plane GaN layer of FIG. 6(a), remarkable roughness was not observed. On the other hand, in the surfaces of the −r-plane GaN layers of FIG. 6(b) and FIG. 7, a stripe-pattern morphology was observed.

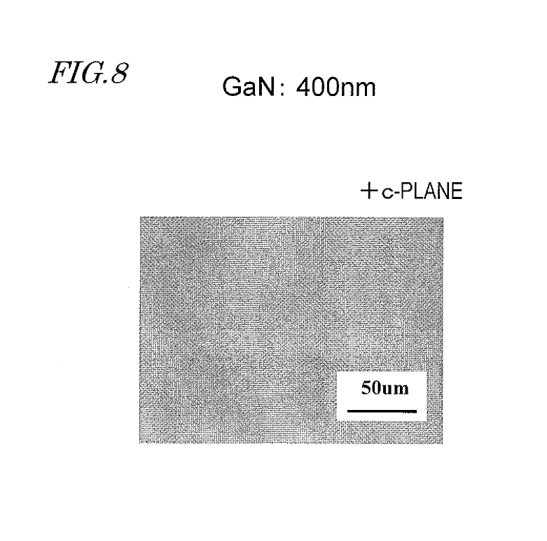

FIG. 8 is an optical-microscopic image of the surface of a +c-plane GaN (thickness: 400 nm). As seen from FIG. 8, the +c-plane is free from a problem which would occur in the −r-plane, so that the formed GaN layer has a smooth surface.

Thus, in a situation that a stripe-pattern morphology is observed as a result of GaN crystal growth on the −r-plane GaN substrate, there is large roughness in the GaN surface. Therefore, formation of a thin light-emitting layer of a usual thickness, e.g., about 3 nm, is difficult, and moreover, there is a probability of a short circuit of an electrode in fabrication of a light-emitting device. Thus, there is a problem that fabrication of a light-emitting device is very difficult.

The present inventor conducted detailed researches and concluded that the roughness in the surface of the GaN layer, which would not cause a problem in the conventional +c-plane GaN, occurs in the −r-plane GaN during a heat treatment, such as thermal cleaning, and this is a cause of an abnormal surface morphology of a stripe pattern. The generation of large roughness due to the abnormal surface morphology of a stripe pattern in the surface of the −r-plane GaN layer is an unknown phenomenon in the conventional c-plane growth technology. Also, this phenomenon would not occur in +r-plane growth.

The present inventor conducted experiments which will be described later and made an inference that the cause of occurrence of abnormality in the surface morphology of the GaN layer is attributed to roughness of the surface of an underlying surface (−r-plane GaN substrate surface) before the growth of the GaN layer, and reached completion of the present invention.

<Experiment as to Surface Roughness by Heat>

First, a +r-plane GaN substrate and a −r-plane GaN substrate were prepared and washed in a mixture solution of sulfuric acid and hydrogen peroxide for 10 minutes. Then, the substrates were subjected to a surface treatment with buffered sulfuric acid for 10 minutes and washed with water for 10 minutes. Thereafter, these GaN substrates were carried into a reaction chamber of a MOCVD apparatus and subjected to a thermal cleaning for 10 minutes in a mixture gas atmosphere of ammonium (nitrogen source gas), hydrogen, and nitrogen while the substrate temperature was at 750° C.

Then, ammonium, hydrogen, nitrogen, trimethylgallium (Group III element source gas) are supplied into the reaction chamber, and a GaN layer having a thickness of 400 nm was grown on the substrate while the substrate temperature was maintained at 750° C. Since the substrate temperature was 750° C. which is lower than a common growth step temperature (e.g., 1000° C.), surface roughness of the grown GaN layer was not observed no matter which substrate the GaN layer was grown on.

Next, the substrate temperature was increased from 750° C. to the respective predetermined temperatures, 850° C., 925° C., 990° C., and 1090° C. During the increase of the temperature from 750° C. to the respective temperatures, ammonium, hydrogen, and nitrogen were contained in the atmosphere.

In the GaN layer grown on the +r-plane GaN substrate, remarkable roughness was not observed in the surface of the GaN layer in any of all the samples of 750° C. to 1090° C. However, as for the −r-plane GaN layer, it was found that roughness was observed in the surface of the GaN layer in the sample of 850° C., and in the samples of 850° C. or higher (e.g., 990° C.), remarkable roughness was produced in the surface of the GaN layer. It is inferred that the roughness in the surface of the GaN layer is attributed to the surface roughness of the underlying −r-plane GaN substrate.

In view of the above, the thermal stability of the surface of the −r-plane GaN substrate is inferior to that of the surface of the +r-plane GaN substrate. It was found that the thermal stability of the material of GaN varies due to the difference in plane orientation, +r-plane and −r-plane, although the sublimation temperature naturally depends on the material.

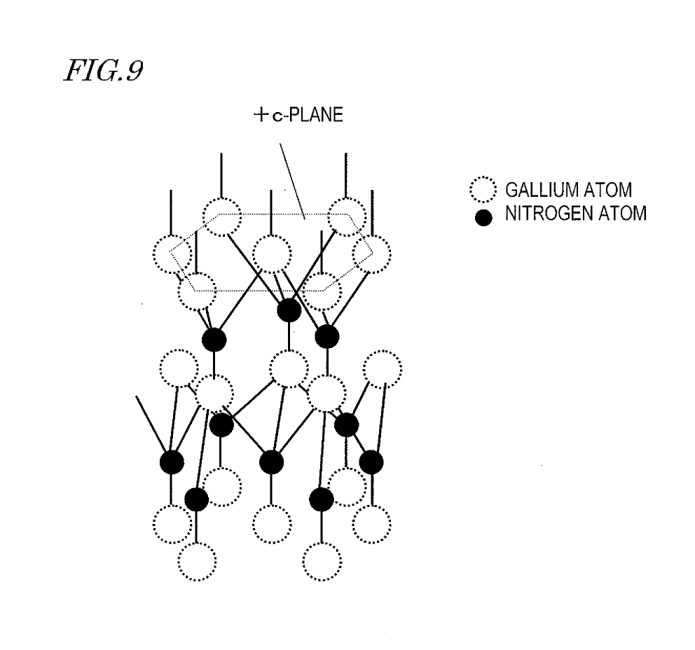

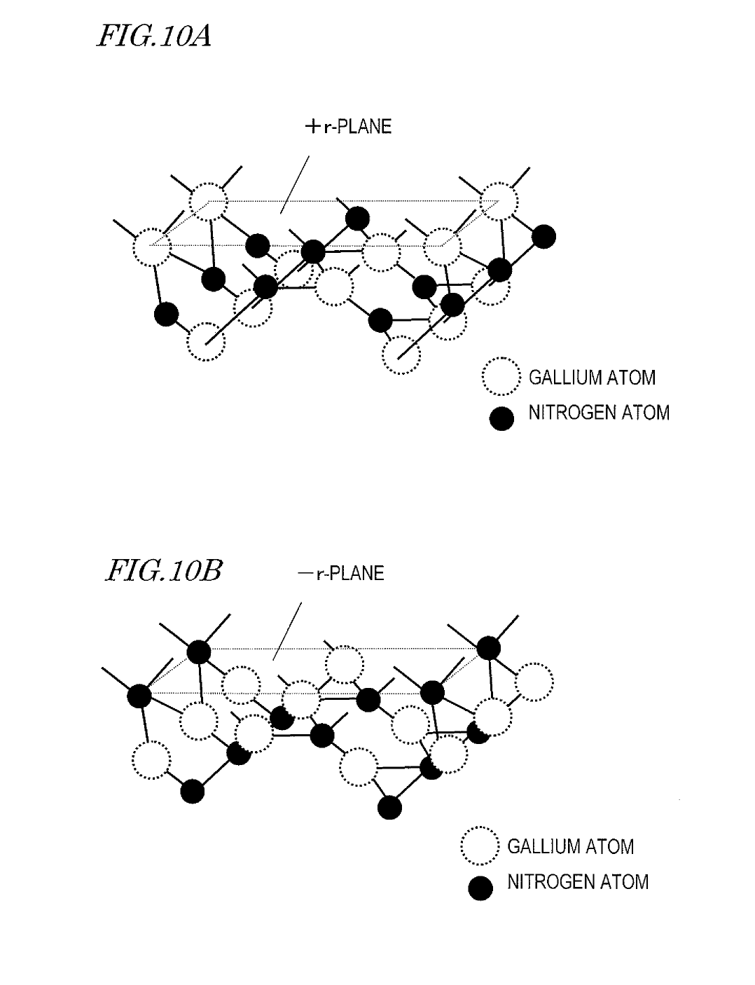

It is inferred that the difference in thermal stability between the +r-plane surface and the −r-plane surface is attributed to the difference in atomic arrangement in the surface. Hereinafter, this inference is described with reference to FIG. 9 and FIGS. 10A and 10B. FIG. 9 is a perspective view schematically showing the structure of a +c-plane GaN crystal. FIG. 10A is a perspective view schematically showing the structure of a +r-plane GaN crystal. FIG. 10B is a perspective view schematically showing the structure of a −r-plane GaN crystal.

As shown in FIG. 9, the surface of +c-plane GaN crystal is terminated with gallium atoms. The outermost gallium atoms each have one upward bond and three downward bonds. The three downward bonds of each of the gallium atoms are bonded to nitrogen atoms so that a stable plane is formed. For example, even if one of the gallium atoms at the surface is eliminated, underlying nitrogen atoms are held by three bonds, so that the +c-plane GaN crystal can be recognized as being stable against elimination of atoms.

At the +r-plane GaN surface of FIG. 10A, the crystal surface is terminated with gallium atoms. On the other hand, at the −r-plane GaN surface of FIG. 10B, the crystal surface is terminated with nitrogen atoms. In a reaction site of gallium nitride, the vapor pressure of nitrogen atom is high. Therefore, a bond of a nitrogen atom and a gallium atom that is present relatively stably is weak, an atomic vacancy of a nitrogen atom readily occurs in a gallium nitride compound. Estimating from such a fact, the outermost surface of the +r-plane is terminated with gallium atoms and is therefore relatively stable even at high temperatures. On the other hand, the outermost surface of the −r-plane is terminated with nitrogen atoms and therefore has low stability against. As a result, in the −r-plane, nitrogen atoms leave from the outermost surface, based on which a roughened structure is then readily formed in the outermost surface. It is estimated that, when the underlayer (−r-plane GaN substrate) has such roughness, epitaxial crystal growth does not uniformly advances so that roughness occurs in the surface of the growing layer.

Conventionally, the method of preventing surface roughness of the GaN substrate has been supplying an ammonium gas to the surface of the GaN substrate during the increase of the substrate temperature. While N atoms are eliminated from the GaN crystals due to the increase of the temperature, an N atom source gas (ammonium) is supplied to the substrate surface, whereby omission of N atoms from the GaN crystal surface is prevented. Patent Document 1 discloses applying the same idea to the m-plane GaN substrate.

However, the present inventor carried out detailed research and made the inference that supplying ammonium during the temperature increasing step cannot sufficiently prevent surface roughness of the −r-plane GaN substrate.

Here, it is inferred that the stripe-pattern surface morphology caused by the −r-plane growth is attributed to surface roughness of the GaN substrate which is caused during the increase of the temperature, and which is not detrimental in the conventional +c-plane GaN.

The present inventor wholeheartedly carried out research on the method of preventing such surface roughness of the −r-plane GaN layer which would occur in the temperature increasing step and found that supplying a Group III element source gas as well as a nitrogen source gas (Group V element source gas) into the reaction chamber during the temperature increasing step can prevent surface roughness of the −r-plane GaN layer.

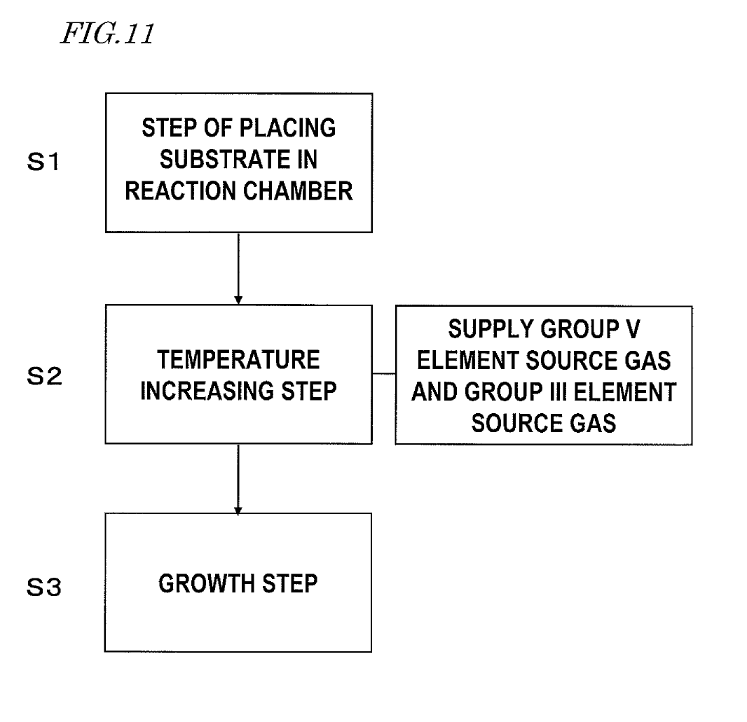

Hereinafter, a method of forming a nitride semiconductor layer according to the present invention is described with reference to FIG. 11 to FIG. 13.

First, refer to FIG. 11. According to the present invention, as shown in FIG. 11, the step (S1) of placing a substrate that includes a nitride semiconductor crystal whose surface is a −r-plane at least in an upper surface in the reaction chamber of the MOCVD apparatus, the step (S2) of increasing the temperature of the substrate by heating the substrate placed in the reaction chamber, and the step (S3) of growing a nitride semiconductor layer on the substrate are performed.

The substrate that includes a nitride semiconductor crystal whose surface is a −r-plane at least in an upper surface is typically a −r-plane GaN substrate. However, such a substrate is not limited to the −r-plane GaN substrate but may be a SiC substrate which includes a −r--plane GaN layer in its surface or a sapphire substrate which includes a −r-plane GaN layer in its surface. The −r-plane nitride semiconductor crystal of the substrate surface is not limited to a GaN crystal but may be an AlₓGa_{y}N layer (0≦x1, 0≦y≦1, x+y=1) crystal. Also, it is not necessary to have a monolayer structure.

The most distinguishing feature of the present invention resides in that the temperature increasing step (S2) includes supplying a nitrogen source gas (Group V element source gas) and a Group III element source gas into the reaction chamber. In the conventional temperature increasing step, ammonium is supplied as a source gas for N atoms that are likely to be eliminated from the GaN crystals, but a Group III element source gas is not supplied. This is because it has been recognized that atoms of Ga that is a Group III element are less likely to be eliminated from the GaN crystal surface than atoms of N that is a Group V element, and therefore, it is not necessary to prevent sublimation of Ga atoms in the temperature increasing step. Also, when the Group III element source gas is supplied together with the nitrogen source gas (ammonium) during the temperature increasing step, growth of a Group III-V compound layer (the GaN layer) begins at a low temperature before an intended growth temperature (typically, 1000° C. of higher) is reached. Thus, it has been estimated that the crystallinity of the GaN layer degrades. As known in the art, the crystallinity of the GaN layer degrades as the growth temperature decreases. Therefore, commonly, the substrate temperature is predetermined to be 1000° C. or higher, and the crystal growth is started after the predetermined temperature is reached.

However, in the case of the −r-plane growth, the present inventor supplied a Group III element source gas (Ga source gas) together with a nitrogen source gas (ammonium) during the temperature increasing step and unexpectedly found that, even when a thin GaN layer (thickness: e.g., 400 nm) was formed, the surface morphology of the GaN layer was significantly improved. The crystal quality of the obtained GaN layer did not significantly degrade. It is inferred that this is because roughness of the underlying surface (−r-plane GaN substrate) which is caused during the temperature increasing step is prevented.

It was experimentally found that a continuous early-stage grown layer of a nitride semiconductor was formed on the substrate during the increase of the temperature, or the surface of the −r-plane nitride semiconductor crystal was maintained smooth although growth of the GaN layer did not occur, depending on the gas supply conditions for the temperature increasing step (S2). In any case, the surface of the finally-obtained GaN layer was smooth.

The nitrogen source gas used in the present invention is typically ammonium. The Group III element source gas may be an organometallic gas, such as trimethylgallium (TMG), triethylgallium (TEG), trimethylindium (TMI), or trimethylaluminum (TMA). The organometallic gas is preferably supplied into the reaction chamber by supplying a mixture gas which contains the organometallic gas and a carrier gas, such as a nitrogen gas or hydrogen gas. Note that, in addition to these source gases, a nitrogen gas or hydrogen gas may be separately supplied into the reaction chamber. When necessary, the gas supplied into the reaction chamber may contain a dopant gas.

The preferred gas supply conditions in the temperature increasing step (S2) are determined depending on the degree of surface roughness (height of roughness) which can be caused during the increase of the temperature while the Group III element source gas is not supplied. Where the height of roughness is H [nm] (e.g., H±10 nm), the supply rate of the source gas is preferably determined to meet such conditions that a GaN layer can be grown to about H [nm] thick, for example.

With the view of stabilizing the crystal growth rate and fabricating a semiconductor device with a high yield, the supply rate of the nitrogen source gas is preferably maintained generally constant throughout the temperature increasing step (S2) and the growth step (S3). Since it is preferred that a crystal layer which is grown in the temperature increasing step (S2) before the predetermined growth temperature is reached is not excessively thick, it is also preferred that the supply rate of the Group III element source gas is relatively small during the temperature increasing step (S2) than during the growth step (S3). As a result of these, the V/Ill ratio in the temperature increasing step (S2) is preferably larger than the V/III ratio in the growth step (S3). The V/III ratio in the temperature increasing step (S2) is set to, for example, 4,000 or higher.

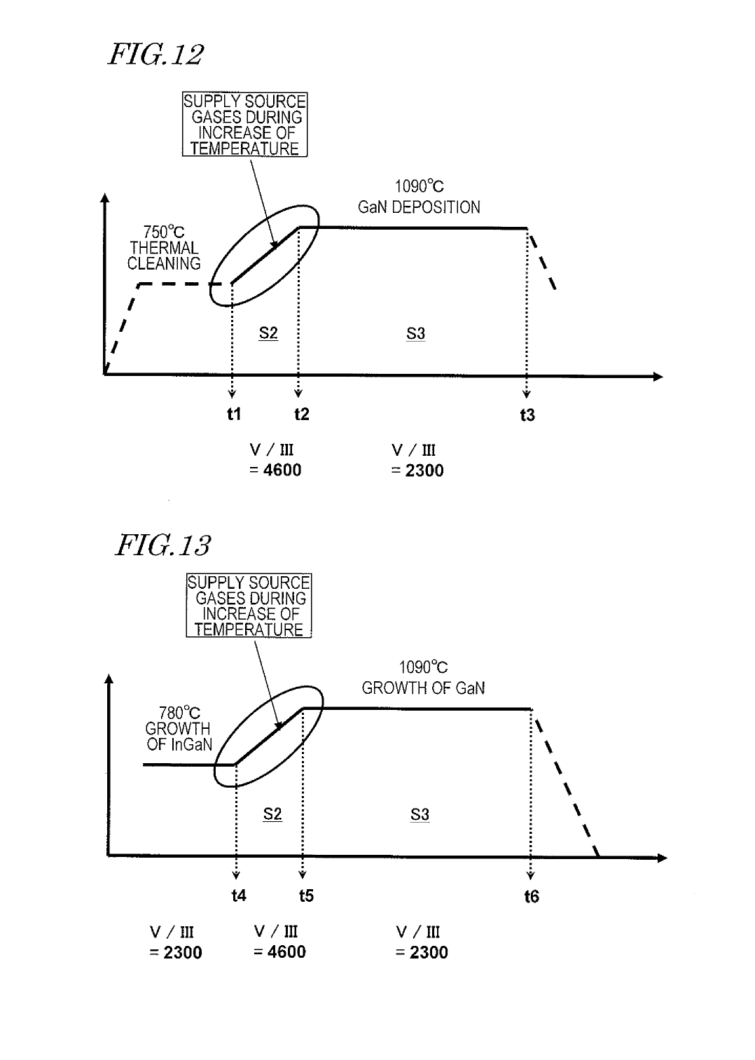

FIG. 12 is a chart that illustrates the process of the present invention. In the chart, the abscissa axis represents the time, and the ordinate axis represents the substrate temperature. The interval from time t1 to time t2 is the temperature increasing step (S2). The interval from time t2 to time t3 is the growth step (S3). As apparent from the comparison with FIG. 5, one of the features of the present invention resides in that the source gases (source gases for N and Ga) are supplied during the increase of the temperature.

The duration from time t1 to time t2 is, for example, from about 3 minutes to about 10 minutes. In this interval from time t1 to time t2, it is not necessary to continuously supply the source gases. The important point is that the nitrogen source gas and the Group III source gas are contained in the atmosphere of the reaction chamber. Therefore, in the temperature increasing step (S2), the supply of the source gases may be periodically or temporarily interrupted so long as the atmosphere of the reaction chamber contains sufficient amounts of the source gases.

The increase rate of the substrate temperature (temperature increase rate) in the temperature increasing step (S2) is set within the range of, for example, 20° C./min to 80° C./min. The temperature increase rate does not need to be constant. In the temperature increasing step, the substrate temperature may be temporarily held at a constant value or may be temporarily decreased.

Note that the temperature increasing step (S2) is not limited to increasing the substrate temperature from the thermal cleaning temperature (from about 600° C. to about 900° C.) to the nitride semiconductor layer growth temperature (from about 850° C. to about 1100° C.) The temperature increasing step (S2) may include increasing the substrate temperature from the growth temperature for the InGaN layer (from about 650° C. to about 850° C.) to the growth temperature for the p-GaN layer (from about 950° C. to about 1100° C.). FIG. 13 is a chart that illustrates an example of the supply of the source gases during the process of increasing the substrate temperature from the growth temperature for the InGaN layer (from about 650° C. to about 850° C.) to the growth temperature for the p-GaN layer (from about 950° C. to about 1100° C.). In the example of FIG. 13, the interval from time t4 to time t5 is the temperature increasing step (S2), and the interval from time t5 to time t6 is the growth step (S3). To smooth the surface of the underlying layer (−r-plane GaN substrate) before the growth of the InGaN layer, it is preferred that the respective steps shown in FIG. 12 are carried out before time t4.

As described above, in the temperature increasing step (S2), when the substrate temperature is 950° C. or higher, Ga atoms and N atoms are incessantly sublimated from the −r-plane GaN surface, so that roughness is likely to be formed in the surface. However, according to the present invention, the Group III element source gas is supplied together with the nitrogen source gas (ammonium), whereby sublimation of Ga atoms from the −r-plane GaN surface as well as sublimation of N atoms can be prevented.

The supply rate of the Group III source gas in the temperature increasing step (S2) is determined such that recesses which would be formed in the surface of the GaN layer due to sublimation of Ga atoms during the increase of the temperature are compensated for. For example, in the case of increasing the temperature from about 750° C. to about 1000° C., on the assumption that recesses of about 160 nm would be formed in the surface of the −r-plane GaN layer under the conventional conditions, the Ga element source gas may be supplied such that a GaN layer is grown so as to have a thickness of about 160 nm or more during the temperature increasing step.

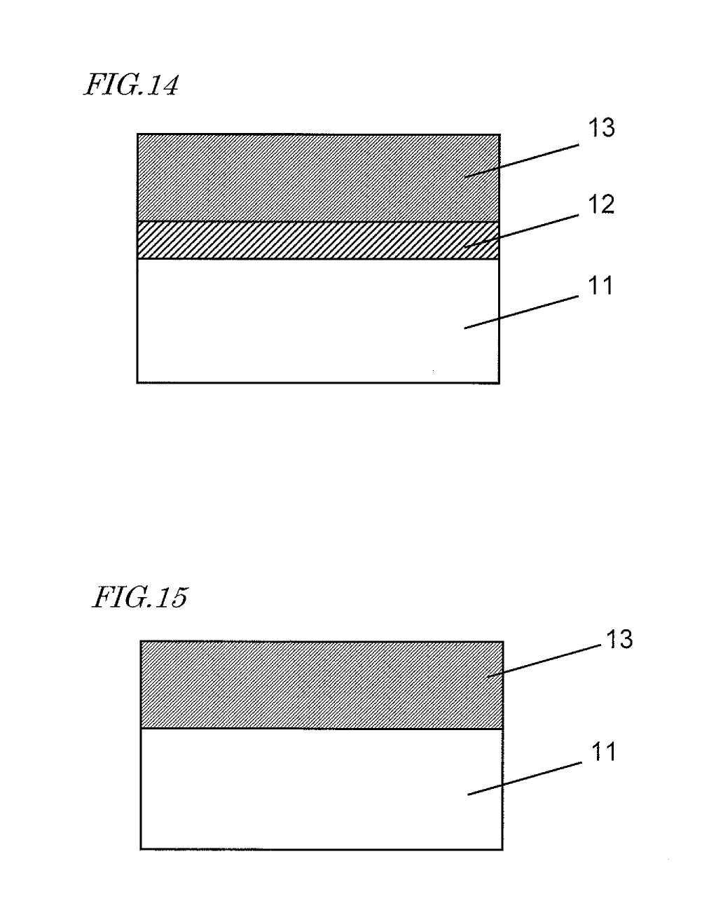

FIG. 14 is a cross-sectional view showing nitride semiconductor layers formed by a nitride semiconductor layer formation method according to the present invention. In the example of FIG. 14, a nitride semiconductor layer 12 and a nitride semiconductor layer 13 are stacked on a −r-plane surface of a GaN substrate 11. The nitride semiconductor layer 12 is formed during the temperature increasing step (S2). The nitride semiconductor layer 13 is formed during the growth step (S3). The nitride semiconductor layer 13 does not need to be a monolayer film of GaN but may be a multilayer film including an AlGaN layer, an InGaN layer, or the like, which contains mixed crystals, or a multilayer film including p-GaN layer, n-GaN layer, or the like.

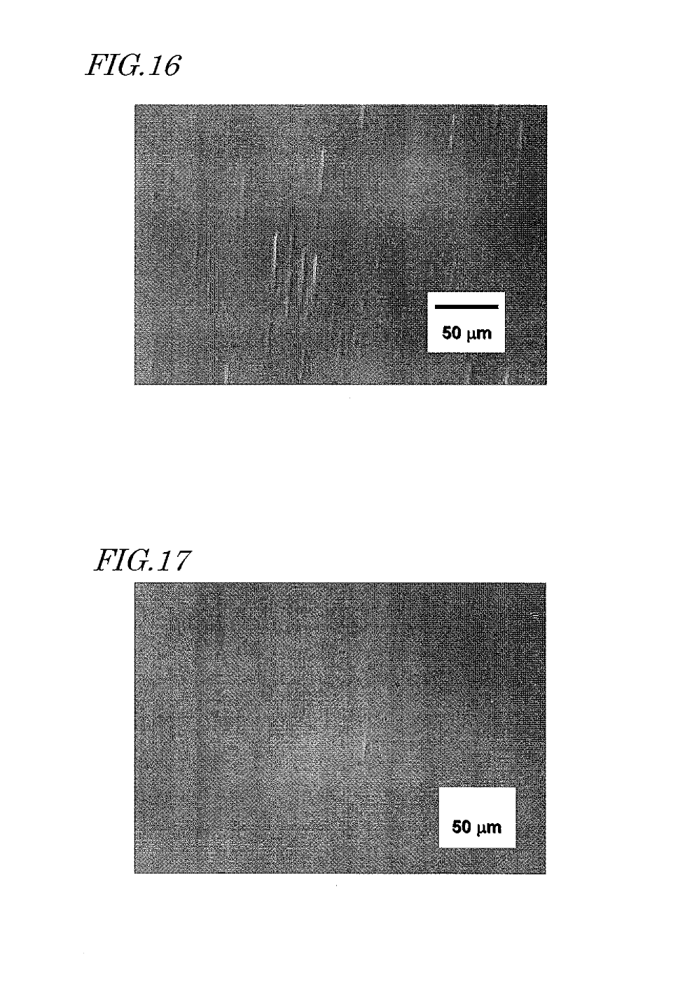

FIG. 15 is another cross-sectional view showing a nitride semiconductor layer formed by a nitride semiconductor layer formation method according to the present invention. The example of FIG. 15 shows a structure which includes a nitride semiconductor layer 13 grown on a −r-plane surface of a GaN substrate 11. The presence of a nitride semiconductor layer formed during the temperature increasing step (S2) cannot be detected. However, the surface of the nitride semiconductor layer 13 has a smooth surface morphology, and it is appreciated that the surface of the −r-plane GaN substrate 11 was maintained smooth in the temperature increasing step (S2).

The temperature increasing step (S2) of the present invention preferably includes increasing the substrate temperature from a temperature lower than 850° C. to a temperature higher than 850° C. According to the above-described experiment, roughness is caused in the surface of the −r-plane GaN layer during the increase of the substrate temperature to a temperature higher than 850° C. Therefore, in the temperature increasing step (S2), when the substrate temperature is increased to 850° C. or higher, supplying a nitrogen source gas and a Group III source gas to a growing plane is important. Thereby, a smooth −r-plane GaN surface can be obtained immediately before the growth step (S3) for the nitride semiconductor layers. Thus, the supply of the source gases in the temperature increasing step (S2) is preferably started before the substrate temperature reaches 850° C.

Note that the growth step (S3) for the nitride semiconductor layers is preferably performed while the substrate temperature is at 990° C. or higher. This is because the effects of the present invention are outstanding when the growth is carried out at such high temperatures.

### EXAMPLE 1

A −r-plane GaN substrate is placed in the MOCVD apparatus and subjected to a heat treatment for 10 minutes at a substrate temperature of 750° C. in a mixture gas atmosphere containing ammonium, hydrogen, and nitrogen.

Then, in an atmosphere containing ammonium, hydrogen, nitrogen, and trimethylgallium, the substrate temperature was increased from 750° C. to 1090° C. The supply ratio of the Group V source material and the Group III source material (V/III ratio) during the increase of the temperature was about 4600. The thickness of the GaN layer grown during the increase of the temperature was calculated at about 150 nm.

After the substrate temperature reached 1090° C., the supply of trimethylgallium was stopped, and the temperature was decreased in a mixture gas atmosphere containing ammonium, hydrogen, and nitrogen.

FIG. 16 is an optical-microscopic image of the surface of the GaN layer grown during the increase of the temperature. An abnormal surface morphology of a stripe pattern was not observed. The surface roughness of this sample was measured by a laser microscope, and the root mean square roughness RMS was 10 nm. In the conventional example, the root mean square roughness RMS of the surface was 71 nm. It is understood that the present invention greatly improved the surface morphology of the GaN layer.

### EXAMPLE 2

A −r-plane GaN substrate was placed in the MOCVD apparatus and subjected to a heat treatment for 10 minutes at a substrate temperature of 750° C. in a mixture gas atmosphere containing ammonium, hydrogen, and nitrogen. Then, the substrate temperature was increased from 750° C. to 1090° C. in an atmosphere containing ammonium, hydrogen, nitrogen, and trimethylgallium. The supply ratio of the Group V source material and the Group III source material (V/III ratio) during the increase of the temperature was about 4600. The thickness of the GaN layer grown during the increase of the temperature was calculated at about 150 nm.

After the substrate temperature reached 1090° C., the supply rate of trimethylgallium was increased, and a 400 nm thick GaN layer was grown in a mixture gas atmosphere containing ammonium, hydrogen, nitrogen, and trimethylgallium. The V/III ratio during the crystal growth of the GaN layer was about 2300. After the growth of the GaN layer, the supply of trimethylgallium was stopped, and the temperature was decreased in a mixture gas atmosphere containing ammonium, hydrogen, and nitrogen.

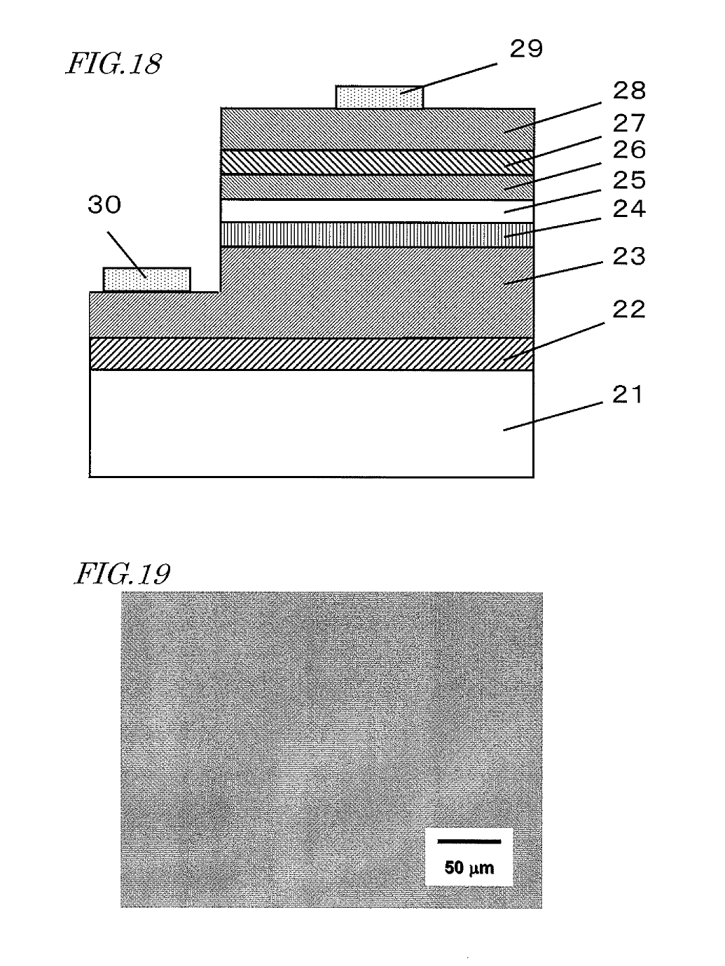

FIG. 17 is an optical-microscopic image of the surface of the above-described GaN layer. An abnormal surface morphology of a stripe pattern was not observed as compared with the conventional example. The surface roughness of this sample was measured by a laser microscope, and the root mean square roughness RMS was 7 nm. In the conventional example, the root mean square roughness RMS of the surface was 50 nm. It is understood that the present invention greatly improved the surface morphology of the GaN layer.

### EXAMPLE 3

An example of a light-emitting device fabricated on a −r-plane GaN substrate using the method of the present invention is described with reference to FIG. 18.

First, a −r-plane GaN substrate 21 was placed in the MOCVD apparatus and subjected to a heat treatment for 10 minutes at a substrate temperature of 750° C. in a mixture gas atmosphere containing ammonium, hydrogen, and nitrogen. Then, the substrate temperature was increased from 750° C. to 1090° C. in an atmosphere containing ammonium, hydrogen, nitrogen, trimethylgallium, and silane. The supply ratio of the Group V source material and the Group III source material (V/III ratio) during the increase of the temperature was about 4600. The thickness of an n-type GaN layer 22 grown during the increase of the temperature was calculated at about 150 nm.

After the substrate temperature reached 1090° C., the supply rate of trimethylgallium was increased, and a 2.5 μm thick n-type GaN layer 23 was grown in a mixture gas atmosphere containing ammonium, hydrogen, nitrogen, trimethylgallium, and silane. The V/III ratio during the crystal growth of the GaN layer was about 2300. Subsequently, the growth temperature was decreased to 780° C., and a light-emitting layer 24 which was constituted of a 9 nm thick InGaN active layer and a 15 nm thick GaN barrier layer was formed. During the decrease of the temperature, the supply of the Group III source material was halted. The In source material used was trimethylindium.

Next, the growth temperature was increased to 995° C. in an atmosphere containing ammonium, hydrogen, nitrogen, and trimethylgallium. The thickness of an undoped GaN layer 25 grown during the increase of the temperature was calculated at about 120 nm. Further, a 5 nm thick first p-GaN layer 26, a 20 nm thick p-AlGaN layer 27, and a 500 nm thick second p-GaN layer 28 were grown. The p-type impurity used was Mg. The Al content in the p-AlGaN layer 27 was about 15%. Then, dry etching was performed with the use of a chlorine gas such that part of the n-type GaN layer 23 was exposed. Thereafter, an n-electrode 30 was formed on the exposed part of the n-type GaN layer 23, and a p-electrode 29 was formed on the p-GaN layer 28, whereby a light-emitting device was fabricated.

Note that the crystal growth of the undoped GaN layer 25 may be produced after the increase of the temperature although in this example it was produced during the increase of the temperature. Specifically, the gallium source gas may be supplied after the increase of the temperature to produce crystal growth of the undoped GaN layer 25, without supplying the gallium source gas during the increase of the temperature from the growth temperature for the light-emitting layer 24. It is preferred however that the undoped GaN layer 25 is formed during the increase of the temperature. This is because generation of roughness in the crystal surface of the light-emitting layer 24 can be prevented during the increase of the temperature.

Alternatively, the first p-GaN layer 26 may be formed directly on the light-emitting layer 24, without forming the undoped GaN layer 25. In this case, the first p-GaN layer 26 may be formed during the increase of the temperature from the growth temperature for the light-emitting layer 24. The first p-GaN layer 26 may be formed after the increase of the temperature.

FIG. 19 is an optical-microscopic image of the surface of the p-GaN layer 28. The total thickness of the nitride semiconductor layers grown on the −r-plane GaN substrate was 3.2 μm. According to the present invention, an excellent surface morphology was realized whereas, when such a thin multilayer structure was formed by the conventional fabrication method, an abnormal surface morphology of a stripe pattern was observed.

### EXAMPLE 4

A light-emitting device was fabricated using the same method as that of Example 3 and measured in terms of the I-V characteristic. Hereinafter, the result of the measurement is described. The light-emitting device of this example was fabricated using the same method as that of Example 3. Specifically, in the fabrication method of the present embodiment, a source gas for Ga was supplied during a temperature increasing step which occurs before the formation of the n-type GaN layer 23 and during a temperature increasing step which occurs after the formation of the light-emitting layer 24 and before the formation of the first p-GaN layer 26. In this example, an electrode constituted of stacked layers of Ti/Al was used as the n-electrode 30, and an electrode constituted of stacked layers of Pd/Pt was used as the p-electrode 29.

The thus-fabricated light-emitting device was evaluated in terms of the I-V characteristic. 95% of samples of the device exhibited excellent I-V characteristic, so that it was found that high fabrication yield was achieved.

### EXAMPLE 5

A light-emitting device was fabricated using a different method from that of Example 3 and measured in terms of the I-V characteristic. Hereinafter, the result of the measurement is described. In this example, a source gas for Ga was not supplied during a temperature increasing step which occurs before the formation of the n-type GaN layer 23, but the source gas for Ga was supplied during a temperature increasing step which occurs after the formation of the light-emitting layer 24 and before the formation of the first p-GaN layer 26.

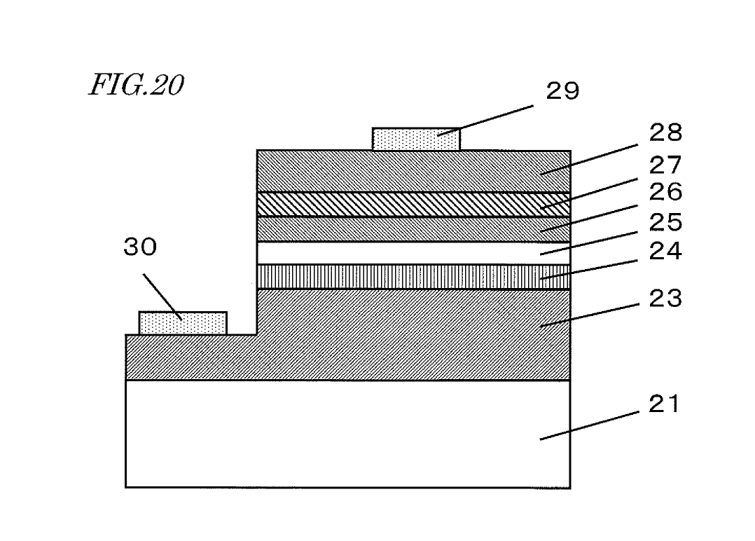

FIG. 20 is a cross-sectional view showing a structure of the light-emitting device of Example 5. In the fabrication method of this example, first, the −r-plane GaN substrate 21 is placed in the MOCVD apparatus and subjected to a heat treatment for 10 minutes at a substrate temperature of 750° C. in a mixture gas atmosphere containing ammonium, hydrogen, and nitrogen. Then, the substrate temperature was increased from 750° C. to 1090° C. in an atmosphere containing ammonium, hydrogen, and nitrogen.

After the substrate temperature reached 1090° C., the supply of trimethylgallium and silane into the MOCVD apparatus is started, and a 2.5 μm thick n-type GaN layer 23 was grown in a mixture gas atmosphere containing ammonium, hydrogen, nitrogen, trimethylgallium, and silane. The V/III ratio during the crystal growth of the GaN layer was about 2300. Subsequently, the growth temperature was decreased to 780° C., and a light-emitting layer 24 which was constituted of a 9 nm thick InGaN active layer and a 15 nm thick GaN barrier layer was formed. During the decrease of the temperature, the supply of the Group III source material was halted. The In source material used was trimethylindium.

Next, the growth temperature was increased to 995° C. in an atmosphere containing ammonium, hydrogen, nitrogen, and trimethylgallium. The thickness of the undoped GaN layer 25 grown during the increase of the temperature was calculated at about 120 nm. A 5 nm thick first p-GaN layer 26, a 20 nm thick p-AlGaN layer 27, and a 500 nm thick second p-GaN layer 28 were grown. The p-type impurity used was Mg. The Al content in the p-AlGaN layer 27 was about 15%. Then, dry etching was performed with the use of a chlorine gas such that part of the n-type GaN layer 23 was exposed. Thereafter, an n-electrode 30 of Pd/PtTi/Al was formed on the exposed part of the n-type GaN layer 23, and a p-electrode 29 of Pd/Pt was formed on the p-GaN layer 28.

The thus-fabricated light-emitting device was evaluated in terms of the I-V characteristic. Only 50% of samples of the device exhibited excellent I-V characteristic.

Comparing Example 4 and Example 5, Example 4 achieved a higher yield than Example 5. It is understood from this result that, in the present invention, a higher yield can be achieved by supplying a source gas for Ga during the temperature increasing step which occurs before the formation of the n-type GaN layer 23 (i.e., the step of forming the n-type GaN layer 22).

According to the present invention, a semiconductor device which includes a multilayer structure of nitride semiconductor layers can be suitably fabricated as described above. However, the present invention is applicable not only to fabrication of a final semiconductor device product but also to fabrication of a substrate which has a high quality epitaxial layer in its surface (“epi wafer”). Specifically, an epi wafer which has the configuration shown in FIG. 14 or FIG. 15 can be fabricated by performing the step of preparing a substrate which includes a nitride semiconductor crystal whose surface is a −r-plane at least in the upper surface and the step of forming a nitride semiconductor layer on the substrate using the above-described nitride semiconductor layer formation method.

Note that an actual −r-plane does not need to be perfectly parallel to the −r-plane but may be inclined from the −r-plane by a small angle (0° to ±1°). The surface (principal surface) of the substrate or semiconductor is sometimes intentionally inclined from the −r-plane by an angle of 1° or greater. In the example described below, both the surface (principal surface) of a GaN substrate and the surface (principal surface) of a nitride semiconductor layer formed on the GaN substrate are intentionally inclined from the −r-plane by an angle of 1° or greater.

### EXAMPLE 6

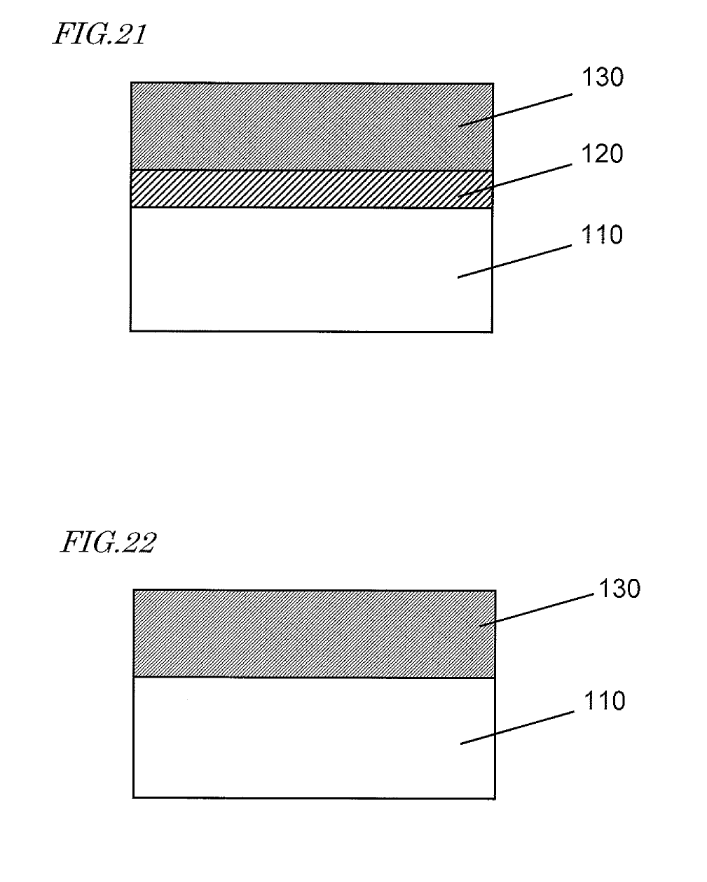

In this example, a GaN substrate whose principal surface is inclined from the −r-plane by an angle of 1° or greater (off-substrate) is used instead of the −r-plane GaN substrate. A GaN substrate 110 shown in FIG. 21 or FIG. 22 is a GaN substrate whose surface is inclined from the −r-plane by an angle of 1° or greater, which is used instead of the GaN substrate 11 of FIG. 14 or FIG. 15. The GaN substrate 110 that has such a configuration is commonly called “off-substrate”. The off-substrate can be formed by performing the step of slicing off a substrate from a monocrystalline ingot and polishing the surface of the substrate such that the surface intentionally inclined in a specific azimuth from the −r-plane is used as the principal surface.

On this GaN substrate 110, a nitride semiconductor layer 120 and a nitride semiconductor layer 130 are formed. The semiconductor layers 120, 130 shown in FIG. 21 or FIG. 22 have a principal surface which is inclined from the −r-plane by an angle of 1° or greater. This is because, when respective semiconductor layers are stacked on the inclined principal surface of the substrate, the surfaces (principal surfaces) of these semiconductor layers are also inclined from the −r-plane.

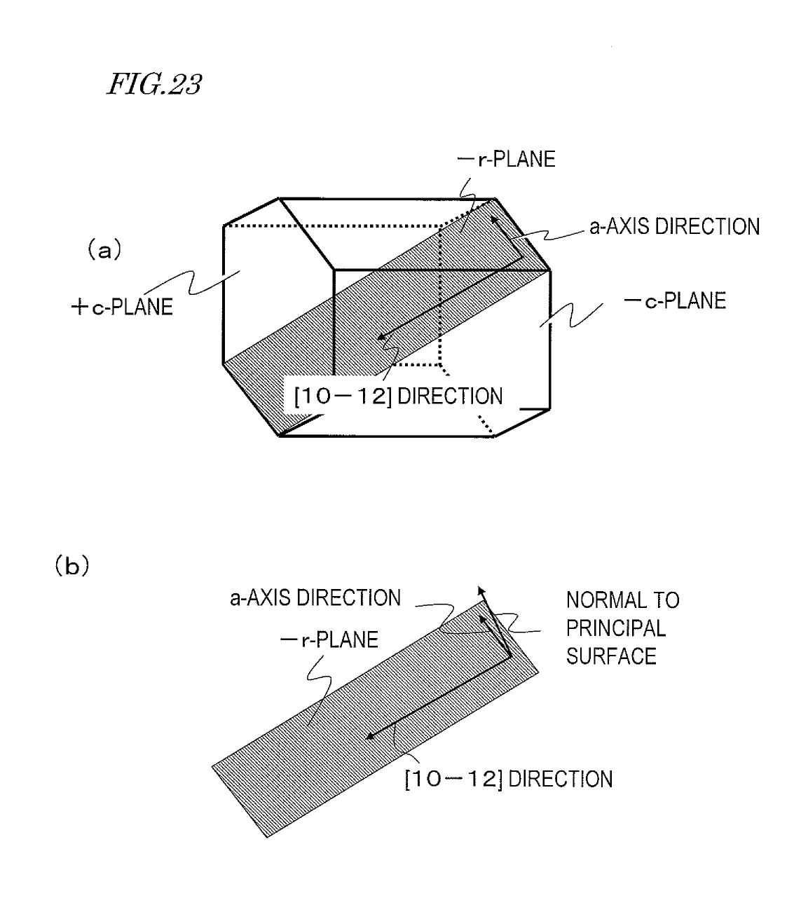

Next, details of the inclination of the GaN substrate in this example is described with reference to FIG. 23.

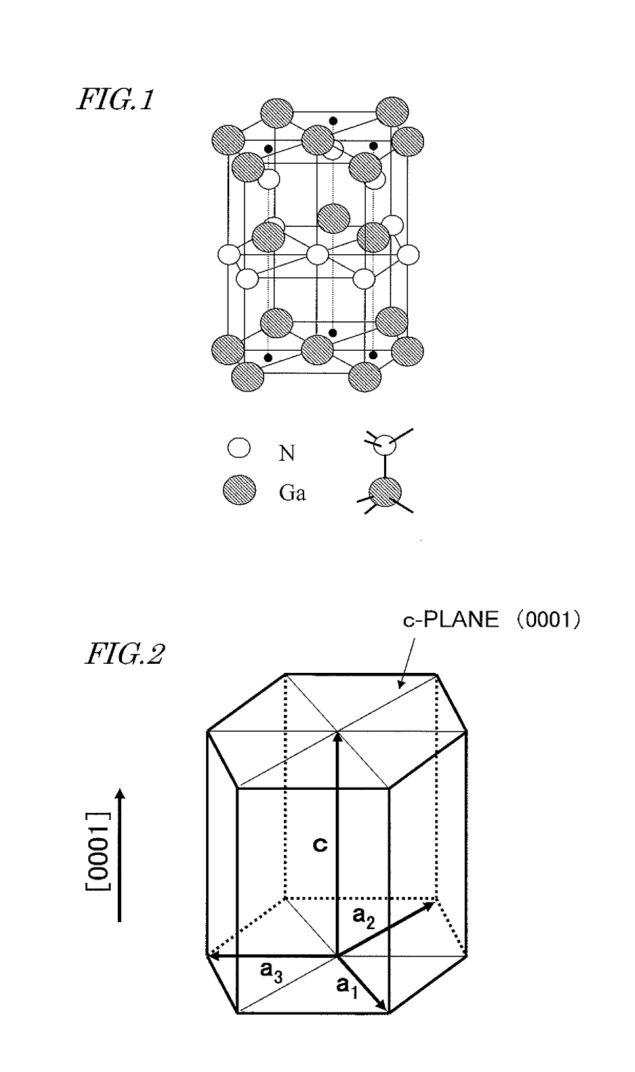

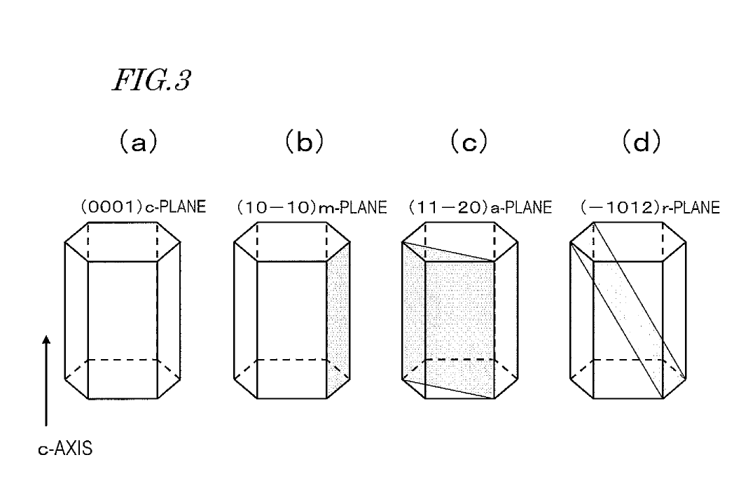

FIG. 23(a) schematically shows the crystalline structure of the GaN substrate (wurtzite crystal structure), corresponding to 90° rotation of the crystalline structure of FIG. 2. The c-planes of the GaN crystal include a +c-plane and a −c-plane. The +c-plane is a (0001) plane over which Ga atoms are exposed and is referred to as “Ga plane”. On the other hand, the −c-plane is a (000-1) plane over which N (nitrogen) atoms are exposed and is referred to as “N plane”. The +c-plane and the −c-plane are parallel to each other. Both of these planes form an angle of 43.2° with the −r-plane. The c-planes have polarity and therefore can be classified into the +c-plane and the −c-plane. Classifying the a-plane that is a non-polar plane into the +a-plane and the −a-plane is nonsensical.

The +c-axis direction shown in FIG. 23(a) is a direction perpendicularly extending from the −c-plane to the +c-plane. On the other hand, the a-axis direction corresponds to the unit vector a₂ of FIG. 2 and is oriented in [−12-10] direction that is parallel to the −r-plane. FIG. 23(b) is a perspective view illustrating the relationship among the normal to the −r-plane, the [10-12] direction, and the a-axis direction. The normal to the −r-plane is parallel to the [20-2-1] direction. As shown in FIG. 23(b), the normal to the −r-plane is perpendicular to both the [10-12] direction and the a-axis direction.

The inclination of the principal surface of the GaN substrate from the −r-plane by an angle of 1° or greater means that the normal to the principal surface of the GaN substrate is inclined from the normal to the −r-plane by an angle of 1° or greater.

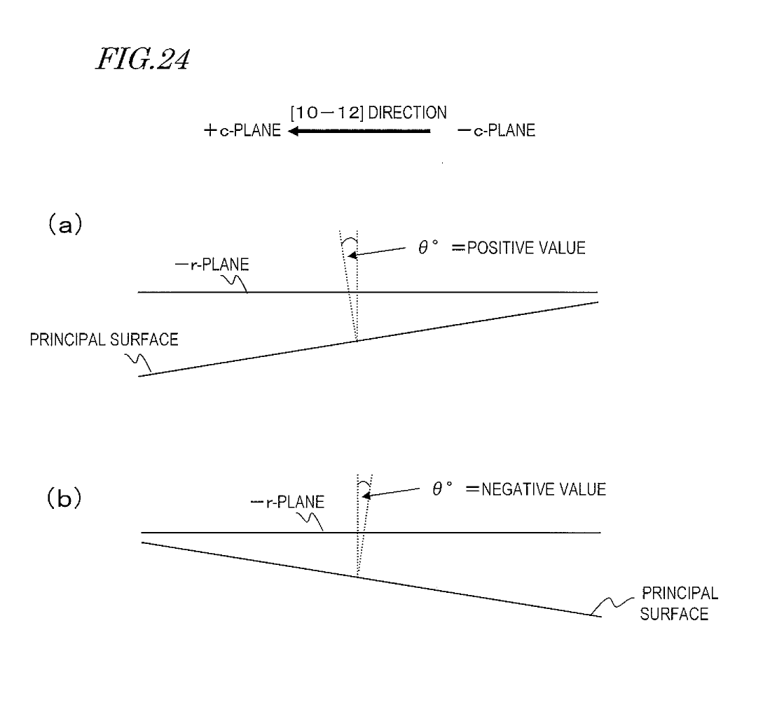

Next, refer to FIG. 24. FIGS. 24(a) and 24(b) are cross-sectional views which illustrate the relationship between the principal surface of the GaN substrate and the −r-plane. These diagrams are cross-sectional views which are perpendicular to both the −r-plane and the c-plane. In FIG. 24, an arrow which represents the [10-12] direction is shown. As shown in FIG. 23, the −r-plane is parallel to the [10-12] direction. Therefore, a normal vector of the −r-plane is perpendicular to the [10-12] direction.

In the examples shown in FIGS. 24(a) and 24(b), the normal vector of the principal surface of the GaN substrate is inclined in the [10-12] direction from the normal vector of the −r-plane. More specifically, in the example of FIG. 24(a), the normal vector of the principal surface is inclined toward the +c-plane side along the [10-12] direction. In the example of FIG. 24(b), the normal vector of the principal surface is inclined toward the −c-plane side along the [10-12] direction. In this specification, the inclination angle of the normal vector of the principal surface relative to the normal vector of the −r-plane (inclination angle θ) in the former case is represented by a positive value, and the inclination angle θ in the latter case is represented by a negative value. In any of these cases, the statement that “the principal surface is inclined in the [10-12] direction” holds true.

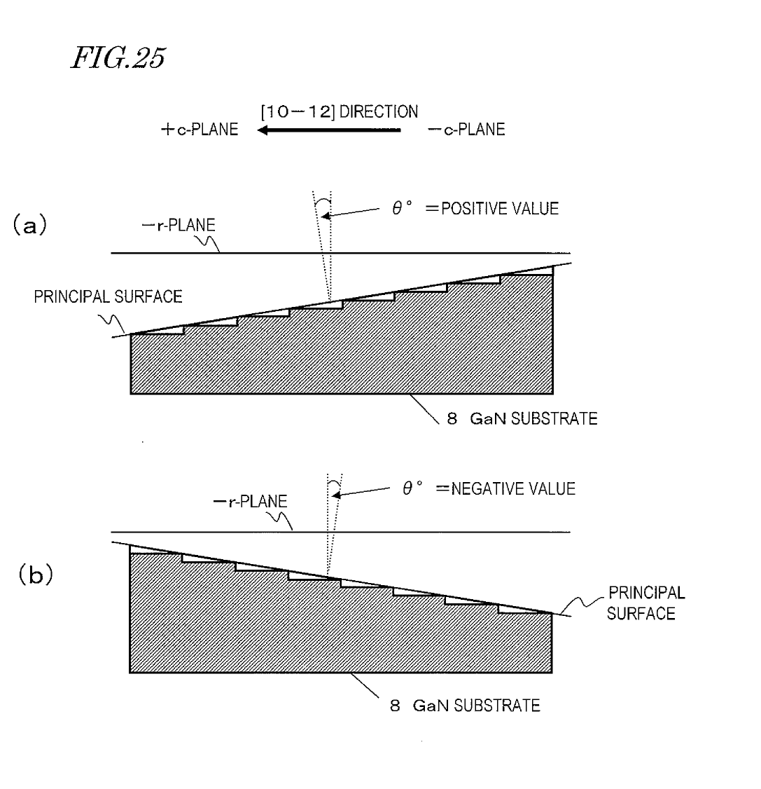

In this example, the inclination angle is in the range of 1° to 5° or in the range of −5° to −1°. In this case, the effects of the present invention can also be provided as well as in the case where the inclination angle is greater than 0° and smaller than ±1°. Hereinafter, the reasons for this are described with reference to FIG. 25. FIGS. 25(a) and 25(b) are cross-sectional views corresponding to FIGS. 24(a) and 24(b), respectively, showing a neighboring region of the principal surface of a GaN substrate 8 which is inclined in the c-axis direction from the −r-plane. When the inclination angle θ is 5° or smaller, the principal surface of the GaN substrate 8 has a plurality of steps as shown in FIGS. 25(a) and 25(b). Each step has a height equivalent to a monoatomic layer (1.6 Å). The steps are arranged parallel to each other with generally equal intervals (30 Å or more). With such an arrangement of the steps, it can be said that the principal surface of the GaN substrate 8 as a whole is inclined from the −r-plane. However, upon closer observation, a large number of −r-plane regions are exposed over the principal surface. The reason why the GaN substrate 8 whose principal surface is inclined from the −r-plane has such a configuration is that the −r-plane as a crystalline plane is intrinsically very stable.

When a GaN-based compound semiconductor layer is formed on the GaN substrate 8 of such a configuration, the principal surface of the GaN-based compound semiconductor layer has a similar shape to that of the principal surface of the GaN substrate 8. Specifically, the principal surface of the GaN-based compound semiconductor layer has a plurality of steps, and the principal surface of the GaN-based compound semiconductor layer as a whole is inclined from the −r-plane.

It is inferred that basically the same phenomenon would occur even when the inclination direction of the normal vector of the principal surface is directed to a plane orientation different from the +c-plane and the −c-plane. When the normal vector of the principal surface is inclined in for example the a-axis direction, basically the same phenomenon occurs so long as the inclination angle is in the range of 1° to 5°.

Note that, when the value of the inclination angle θ is smaller than −5°, the effect of a piezoelectric field increase, and accordingly, the internal quantum efficiency deteriorates. As such, if the piezoelectric field frequently occurs, realizing a semiconductor light-emitting device by means of −r-plane growth has a small significance. When the value of the inclination angle θ is greater than −5°, the interval of the steps decreases, so that excellent crystal growth cannot be obtained. Thus, according to the present invention, the absolute value of the inclination angle θ is limited to 5° or smaller. However, even when the inclination angle θ is set to for example 5°, the actual inclination angle θ may deviate from 5° by about ±1° due to variations in fabrication. Completely removing the variations in fabrication is difficult, while such a small angle deviation would not interrupt the effects of the present invention.

### INDUSTRIAL APPLICABILITY

The present invention can prevent abnormal growth of a stripe pattern, which has been a problem in crystal growth on a −r-plane surface of a GaN substrate, thereby greatly improving the surface morphology. According to the present invention, a thin GaN layer having a thickness of about 400 nm can be grown so as to have a uniform thickness, so that a GaN film which has a large thickness is unnecessary. This greatly improves the throughput in crystal growth for light-emitting devices.

### REFERENCE SIGNS LIST

8 semiconductor layer
11 −r-plane GaN substrate
12 nitride semiconductor layer grown during the increase of the temperature
13 nitride semiconductor layer
21 −r-plane GaN substrate
22 n-type GaN layer during the increase of the temperature
23 n-type GaN layer
24 InGaN light-emitting layer
25 undoped GaN layer grown during the increase of the temperature
26 first p-GaN layer
27 p-AlGaN layer
28 second p-GaN layer
29 p-electrode
30 n-electrode

1. A nitride semiconductor layer formation method in which a nitride semiconductor layer is grown by means of metallorganic chemical vapor deposition, comprising the steps of:
(S1) placing a substrate in a reaction chamber, the substrate including a nitride semiconductor crystal whose surface is a −r-plane at least in an upper surface;
(S2) increasing a temperature of the substrate by heating the substrate placed in the reaction chamber; and
(S3) growing a nitride semiconductor layer on the substrate after the temperature increasing step (S2),
wherein the temperature increasing step (S2) includes supplying a nitrogen source gas and a Group III element source gas into the reaction chamber.

2. The method of claim 1, wherein the temperature increasing step (S2) includes forming a continuous early-stage grown layer of a nitride semiconductor on the substrate during the increase of the temperature.

3. The method of claim 1 wherein, throughout the temperature increasing step (S2) and the growth step (S3), the surface of the nitride semiconductor crystal is maintained smooth.

4. The method of claim 1 wherein, where a ratio of a supply rate of the nitrogen source gas to a supply rate of the Group III element source gas is referred to as a V/III ratio, a V/III ratio in the temperature increasing step (S2) is greater than a V/III ratio in the growth step (S3).

5. (canceled)

6. The method of claim 1, wherein a supply rate of the Group III element source gas supplied into the reaction chamber in the temperature increasing step (S2) is smaller than a supply rate of the Group III element source gas supplied into the reaction chamber in the growth step (S3).

7.-9. (canceled)

10. The method of claim 1, wherein the supply of the nitrogen source gas and the Group III element source gas into the reaction chamber is started before the temperature of the substrate reaches 850° C.

11. The method of claim 1, wherein the supply of the nitrogen source gas and the Group III element source gas into the reaction chamber is started in the middle of the increase of the temperature in the temperature increasing step (S2).

12. The method of claim 1, wherein the temperature increasing step (S2) includes increasing the temperature from a thermal cleaning temperature to a growth temperature for an n-type nitride semiconductor layer.

13. The method of claim 1, wherein the temperature increasing step (S2) includes increasing the temperature from a growth temperature for an InGaN active layer to a growth temperature for a p-GaN layer.

14.-15. (canceled)

16. The method of claim 1, wherein the growth step (S3) includes growing the nitride semiconductor layer to a thickness equal to or smaller than 5 μm.

17. A method of fabricating a semiconductor device, comprising the steps of:
preparing a substrate including a nitride semiconductor crystal whose surface is a −r-plane at least in an upper surface; and
forming a semiconductor multilayer structure on the substrate,
wherein the step of forming the semiconductor multilayer structure includes forming a nitride semiconductor layer in accordance with the nitride semiconductor layer formation method as set forth in claim 1.

18. The method of claim 17, further comprising the step of removing at least part of the substrate.

19. A method of fabricating an epi wafer, comprising the steps of:
preparing a substrate including a nitride semiconductor crystal whose surface is a −r-plane at least in an upper surface; and
forming a nitride semiconductor layer on the substrate in accordance with the nitride semiconductor layer formation method as set forth in claim 1.

20. A nitride semiconductor layer formation method in which a nitride semiconductor layer is grown by means of metallorganic chemical vapor deposition, comprising the steps of:
(S1) placing a substrate in a reaction chamber, the substrate including a nitride semiconductor crystal at least in an upper surface, and an angle formed by a normal to the upper surface and a normal to a −r-plane being from 1° to 5°;
(S2) increasing a temperature of the substrate by heating the substrate placed in the reaction chamber; and
(S3) growing a nitride semiconductor layer on the substrate after the temperature increasing step (S2),
wherein the temperature increasing step (S2) includes supplying a nitrogen source gas and a Group III element source gas into the reaction chamber.

21. The method of claim 20, wherein the substrate has an inclination in a [10-12] direction or a-axis direction.

22. The method of claim 10, wherein the supply of the nitrogen source gas and the Group III element source gas into the reaction chamber is started after the temperature of the substrate reaches 600° C.

23. The method of claim 1, wherein the temperature increasing step (S2) includes
a step of increasing the temperature from a thermal cleaning temperature to a growth temperature for an n-type nitride semiconductor layer and a step of increasing the temperature from a growth temperature for an InGaN active layer to a growth temperature for a p-GaN layer, or
a step of increasing the temperature from the thermal cleaning temperature to the growth temperature for an n-type nitride semiconductor layer and a step of increasing the temperature from the growth temperature for an InGaN active layer to a growth temperature for a undoped GaN layer.

24. The method of claim 1, wherein a thickness of the nitride semiconductor layer grown in the temperature increasing step (S2) is determined depending on a height of surface roughness which can be caused during the temperature increasing step (S2) while the Group III element source gas is not supplied.

25. The method of claim 20, wherein the supply of the nitrogen source gas and the Group III element source gas into the reaction chamber is started before the temperature of the substrate reaches 950° C.

26. The method of claim 20, wherein the temperature increasing step (S2) includes
a step of increasing the temperature from a thermal cleaning temperature to a growth temperature for an n-type nitride semiconductor layer and a step of increasing the temperature from a growth temperature for an InGaN active layer to a growth temperature for a p-GaN layer, or
a step of increasing the temperature from the thermal cleaning temperature to the growth temperature for an n-type nitride semiconductor layer and a step of increasing the temperature from the growth temperature for an InGaN active layer to a growth temperature for a undoped GaN layer.

27. The method of claim 20, wherein a supply rate of the Group III element source gas supplied into the reaction chamber in the temperature increasing step (S2) is smaller than a supply rate of the Group III element source gas supplied into the reaction chamber in the growth step (S3).

28. The method of claim 20, wherein a thickness of the nitride semiconductor layer grown in the temperature increasing step (S2) is determined depending on a height of surface roughness which can be caused during the temperature increasing step (S2) while the Group III element source gas is not supplied.
